(19) United States
(12) Patent Application Publication
(10) Pub. No.: US 2012/0193803 A1
(43) Pub. Date: Aug. 2, 2012

(54) SEMICONDUCTOR DEVICE, METHOD FOR PRODUCING SEMICONDUCTOR DEVICE, AND DISPLAY

(75) Inventors: Isao Yoshino, Kanagawa (JP); Toru Kume, Kanagawa (JP)

(73) Assignee: Renesas Electronics Corporation

(21) Appl. No.: 13/363,954

(22) Filed: Feb. 1, 2012

(30) Foreign Application Priority Data
Jan. 28, 2011 (JP) 2011-024629

(51) Int. Cl. H01L 23/48; H01L 21/50

(52) U.S. Cl. 257/773; 438/106; 257/E23.01; 257/E21.499

(57) ABSTRACT

It is desired to enhance reliability of thermal coupling between a semiconductor chip and a radiating member. A driver assembly has a sheetlike wiring sheet on which lead wires are provided, a driver chip that is mounted over the wiring sheet and is electrically coupled to the lead wire, and a radiator plate in which a housing part for partially housing the driver chip is provided and that is thermally coupled to the driver chip, wherein the wiring sheet and the radiator plate are adhered to each other so as to sandwich the driver chip housed in the housing part between them, and a depth profile of the housing part is set so that the wiring sheet may approach toward the radiator plate side as the wiring sheet extends in such a direction that so as to separate from the driver chip.

### CROSS-REFERENCE TO RELATED APPLICATIONS

The disclosure of Japanese Patent Application No. 2011-24629 filed on Feb. 8, 2011 including the specification, drawings and abstract is incorporated herein by reference in its entirety.

### BACKGROUND

The present invention relates to a semiconductor device, a method for producing the semiconductor device, and a display.

With increasing resolution and increasing screen size of displays (plasma displays, liquid crystal displays, organic electroluminescence displays, etc.), securing of exothermic measure of drivers integrated into the displays is strongly demanded. This is because if the driver fails in its operation due to a thermal influence after being integrated in the display, the entire display will be treated as a malfunctioning product. Incidentally, in connection with higher resolution and larger screen size of the display, a driving load capacity of the driver integrated therein increases, power consumption of the driver grows, and a heating value accompanied with the operation of the driver augments.

Japanese Unexamined Patent Application Publication No. 2010-287866 discloses a technology where an SOI chip is mounted on a radiator plate through heat dissipation grease, and a structural substrate of the SOI chip is electrically coupled to the radiator plate (See FIG. 3 of Japanese Unexamined Patent Application Publication No. 2010-287866). By this, stabilization of GND potential of an address driver IC is attained by reducing wiring impedance between the address driver IC and a system GND.

US Patent Application Publication No. US2008/0023822 discloses a COF (Chip On Flexible printed circuit) type semiconductor package (see FIG. 2 of the document). As shown in FIG. 2 of the document, an IC chip is mounted over a flexible film and a heat pad is mounted over the flexible film in a mode of wrapping the IC chip. The IC chip and the heat pad are adhered to each other through an adhesive layer existing between opposing faces of the both components. Heat produced by the IC chip is allowed to radiate through the heat pad. In the document, a fact that the IC chip is separated from the heat pad by a stress given to parts indicated by B and C of FIG. 2 was pointed as a problem at issue. In the document, there is a contrivance that a slot is provided to the heat pad, so that a corner of the IC chip is held by the slot (for example, see FIG. 6A to FIG. 8B of the document).

### SUMMARY

After being integrated into the display, the mounted substrate of the driver element, the radiator plate that is thermally coupled to the driver element, etc. are assumed to expand or contract due to heat generation of the driver element, heat generation of other devices, etc. Owing to influences of thermal expansion itself of the mounted substrate or difference in thermal expansion between the mounted substrate and the radiator plate etc., there may be cases where positional displacement between the driver element and the radiator plate is invited. There is also a possibility that positional fluctuation between the driver element and the radiator plate is repeated by continuity of operation/non-operation of the driver element. Although specific mechanisms depend on individual cases, thermal influence after the driver element was integrated into the display may deteriorate exhaustion of heat from the driver element to the radiator plate. Incidentally, it is considered that a deterioration mechanism of the exhaustion of heat from the driver element to the radiator plate depends on a configuration of a driver assembly, an assembly mode of the driver assembly to a liquid crystal display, etc.

As is clear from the above-mentioned explanation, enhancing reliability of thermal coupling between a semiconductor chip and a radiating member is being strongly desired. Incidentally, although the problem was explained taking the display as one example, it is not allowed to interpret a technical scope of the present invention narrower taking this point as a reason for doing so. The present invention can be applied to various kinds of semiconductor chips, and it should not be limited to the semiconductor chip to be integrated into the display. Moreover, a timing at which the thermal coupling between the semiconductor chip and the radiating member starts to deteriorate is arbitrary, and should not be restricted to a case after assembly into the display. A cause that deteriorates the thermal coupling between the semiconductor chip and the radiating member is arbitrary, and may be any cause other than the thermal influence described above (for example, a mechanical stress).

According to one aspect of the present invention, a semiconductor device includes: a sheet-like wiring member on which lead wires are provided; the semiconductor chip that is mounted over the wiring member and is electrically coupled to the lead wire; and the radiating member in which a housing part for partially housing the semiconductor chip and that is thermally coupled to the semiconductor chip; wherein the wiring member and the radiating member are adhered to each other so that they may sandwich the semiconductor chip housed in the housing part, and a depth profile of the housing part is set so that the wiring part may approach toward the radiating member side as the wiring member extends in such a direction as to separate from the semiconductor chip. By adopting this configuration, it becomes possible to produce a force that increases adhesion between the semiconductor chip and the radiating member, and thereby to enhance the reliability of the thermal coupling between the semiconductor chip and the radiating member effectively.

According to another aspect of the present invention, a method for producing a semiconductor device includes: electrically connecting the semiconductor chip to the sheetlike wiring member on which the lead wire is provided; forming a housing part for partially housing the semiconductor chip in the radiating member; housing and thermally connecting the semiconductor chip in the housing part of the radiating member; and adhering the wiring member and the radiating member to each other by setting the depth profile of the housing part so that the wiring part may approach toward the radiating member side as the wiring member extends in such a direction as to separate from the semiconductor chip.

According to the present invention, it is possible to enhance the reliability of the thermal coupling between the semiconductor chip and the radiating member effectively.

### BRIEF DESCRIPTION OF THE DRAWINGS

FIG. 1 is a top view of a driver assembly according to a first embodiment;

FIG. 2 is a rear view of the driver assembly according to the first embodiment;

FIG. 3 is a sectional schematic diagram of the driver assembly according to the first embodiment;

FIG. 4 is an enlarged sectional schematic diagram of the driver assembly according to the first embodiment;

FIG. 5 is an enlarged sectional schematic diagram of the driver assembly according to the first embodiment;

FIG. 6 is a manufacturing process diagram of the driver assembly according to the first embodiment;

FIGS. 7A, 7B, and 7B are manufacturing process diagrams of the driver assembly according to the first embodiment, in which FIG. 7A is press working of a tabular metal plate, FIG. 7B is application of grease on a bottom of a concave part of a radiator plate, and FIG. 7C is application of an adhesive agent on a brim part located in an outer circumference of the concave part of the radiator plate;

FIGS. 8A and 8B are manufacturing process diagrams of the driver assembly according to the first embodiment, in which FIG. 8A is a contact of a driver chip placed over the bottom of the concave part of the radiator part and the grease applied to the bottom of the concave part, and FIG. 8B is adhesion of a wiring sheet and the brim part and adhesion of the wiring sheet and the radiator plate;

FIG. 9 is a top view of a driver assembly according to a second embodiment;

FIG. 10 is a sectional schematic diagram of the driver assembly according to the second embodiment;

FIG. 11 is a top view of a driver assembly according to a third embodiment;

FIG. 12 is a sectional schematic diagram of the driver assembly according to the third embodiment;

FIG. 13 is an outline diagram showing a display according to a fourth embodiment; and

FIG. 14 is a schematic diagram showing an assembly state of a driver assembly according to the fourth embodiment.

### DETAILED DESCRIPTION

### First Embodiment

Hereafter, embodiments of the present invention will be described with reference to drawings. In this embodiment, a housing part for partially housing a semiconductor chip of an arbitrary kind is provided in a radiating member that is thermally coupled to the semiconductor chip. The wiring member on which the semiconductor chip is mounted and the radiating member are adhered to each other so that they may sandwich the semiconductor chip housed in the housing part. A depth of the housing part is set so that the wiring member may approach toward the radiating member side as the wiring member extends in such a direction so as to separate from the semiconductor chip. This can enhance effectively reliability of thermal coupling between the semiconductor chip and the radiating member.

A specific mechanism that increases the reliability of the thermal coupling between the semiconductor chip and the radiating member depends on individual cases, but a technical study in a current stage will be explained. In the case where the wiring member is installed being warped relatively to a direction of the radiating member, if the radiating member makes larger thermal expansion than the wiring member, the wiring member adhered to the radiating member receives a stretching force in a linear expansion direction according to linear expansion of the radiating member, and the semiconductor chip mounted on the wiring member will be biased to the radiating member side. This is because since a driver assembly is configured so that the wiring member may approach toward the radiating member side as the wiring member extends in such a direction so as to separate from the semiconductor chip by the depth profile setting of the housing part, the housing part receives a force in such a direction that its depth of the housing part becomes shallower by the wiring member receiving a tensile force. In the case where the radiating member is installed being relatively warped in a direction of the wiring member, when the wiring member also makes larger thermal expansion than the radiating member, the same effect can be attained.

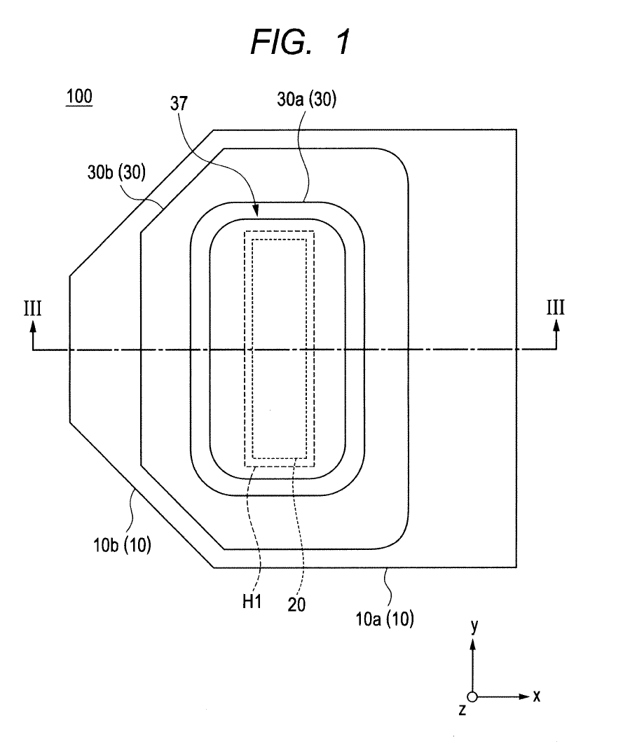

Hereafter, this embodiment will be explained referring to FIGS. 1 to 8. Note that, although a driver integrated into a display will be explained as an example below, a technical scope of this application of the preset invention should not be limited to this, and the present invention can be applied to various other assemblies.

Incidentally, terms indicating directions of up, down, left, right, etc. are premised on seeing the drawing directly from the front. The drawings are prepared mainly for the purpose of explaining the invention, and may not reflect actual dimensions. The technical explanation given below is one at the time of the application, and can include points that are improved through progresses of the technology made later than it.

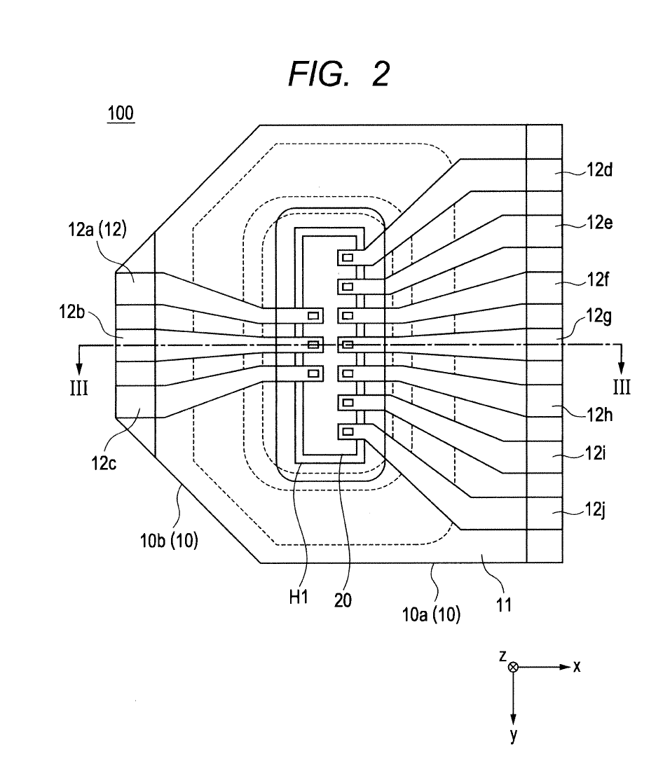

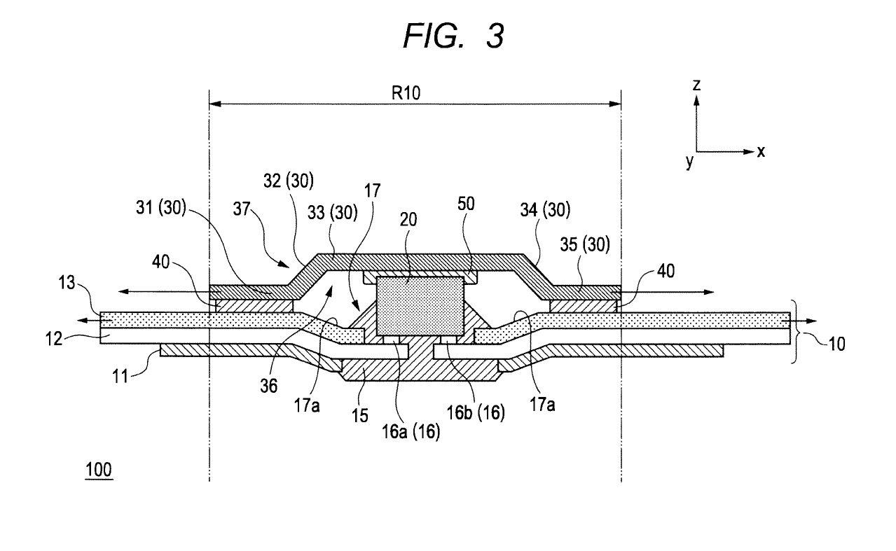

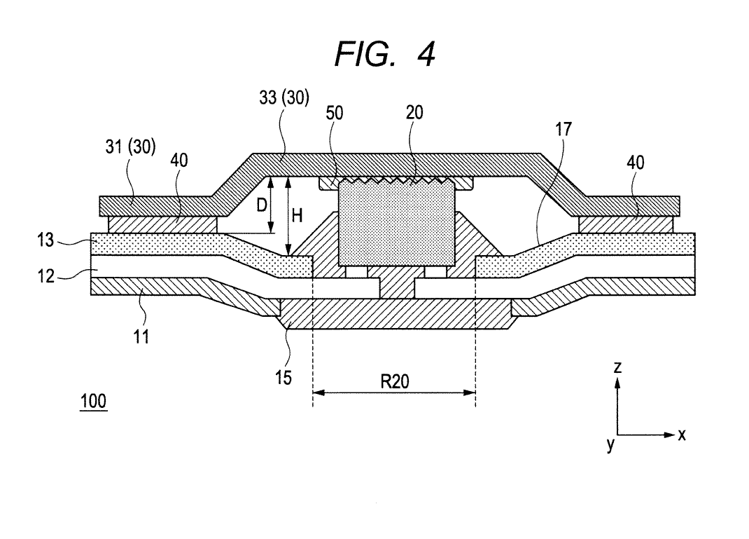

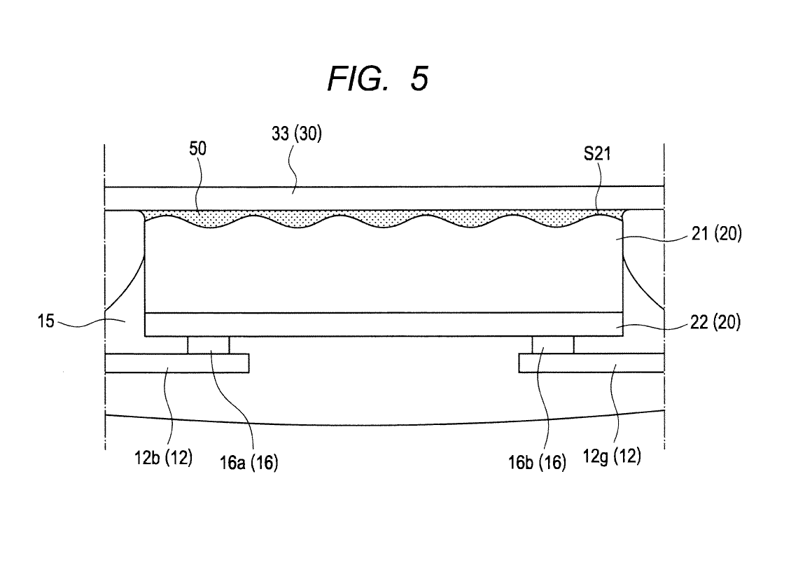

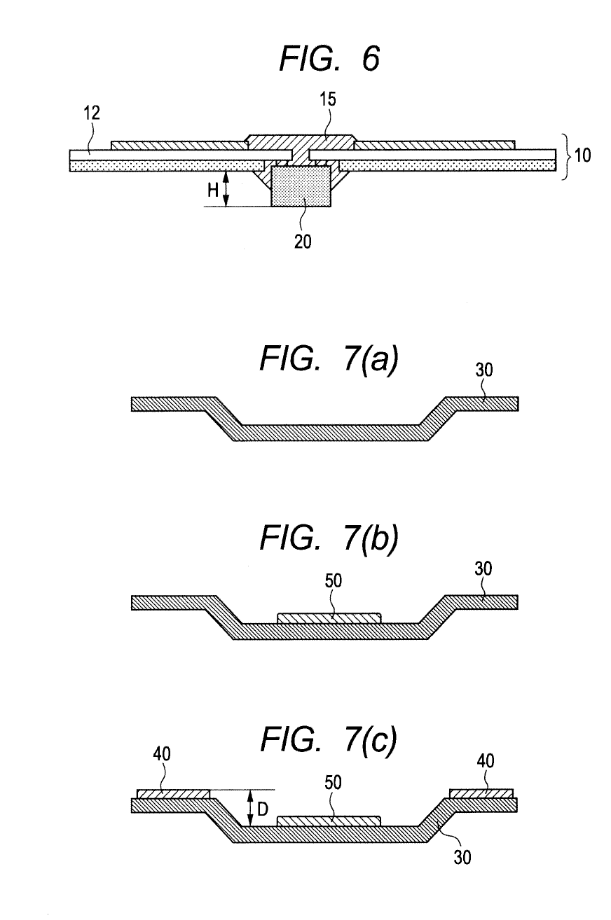

FIG. 1 is a top view of the driver assembly. FIG. 2 is a rear view of the driver assembly. FIG. 3 is a sectional schematic diagram of the driver assembly. FIG. 4 and FIG. 5 are enlarged sectional schematic diagrams of the driver assembly. FIG. 6 to FIG. 8 are manufacturing process diagrams of the driver assembly.

As shown in FIG. 1 to FIG. 3 (especially in FIG. 3), a driver assembly (semiconductor device) 100 is a laminate component in which a wiring sheet (wiring member) 10, the driver chip (the semiconductor chip, or an IC (Integrated Circuit) chip) 20, and a radiator plate (a radiating member) 30 are the layered in this order. The driver chip 20 is fixed over the wiring sheet 10 by a sealing resin (a sealing material, a sealing part) 15. A radiator plate 30 is adhered over the wiring sheet 10 through an adhesive agent (bonding part) 40. Grease (fluid material having heat transference) 50 lies between the top face of the driver chip 20 and the rear face of the radiator plate 30. Incidentally, the wiring sheet 10 is a laminate member in which an insulating layer 11, a lead wire layer (hereinafter, the lead wire layer may be called simply lead wire) 12, and a film layer 13 are layered.

As is clear from FIG. 1 to FIG. 3, the driver chip 20 is mounted on the wiring sheet 10 by inner lead bonding. The wiring sheet 10 is bonded to an external device by outer lead bonding. A driver assembly 100 has flexibility as a whole, and is integrated into the display, being bent in a U-shaped form.

As shown in FIG. 1, the wiring sheet 10 has a rectangular part 10a and a taper part 10b. The radiator plate 30 has a rectangular part 30a and a taper part 30b like the wiring sheet 10. As shown in FIG. 2, lead wires 12a to 12c are provided in the taper part 10b, and lead wires 12d to 12j are provided in the rectangular part 10a. As is clear from FIG. 1 and FIG. 2, a top view shape of the wiring sheet 10 is one that complies with an arrangement mode of the lead wire. Although a smaller number of lead wires are used to show the wiring sheet, actually, the lead wires arranged in the taper part are input terminals of the driver and power source terminals, and the number of the lead wires is in the order of about over ten. The lead wires arranged in the rectangular part are output terminals of the driver, and the number of the lead wires is a few hundreds to over one thousand in some cases. It is common to set a pitch of the terminals of the lead wires in the rectangular part as a minimum pitch, and to design a pitch of the terminals of the lead wires of the taper part to be larger than the minimum pitch.

As shown in FIG. 2, the both ends of each of the lead wires 12a-12j are exposed from the insulating layer 11. A right end of the lead wire 12a is bump-coupled (inner lead bonding) to a left terminal of the driver chip 20. The lead wires 12b and 12c are bump coupled similarly. A left end of the lead wire 12d is bump coupled to a right terminal of the driver chip 20. The lead wires 12e to 12j are bump coupled similarly. Incidentally, the number of lead wires and its wiring mode are arbitrary. The driver chip 20 is provided with a left terminal row in which three terminals are arranged and a right terminal row in which seven terminals are arranged. The number of terminals provided in the driver chip 20 is arbitrary. A lead wire group comprised of the lead wires 12a to 12c has a larger width with increasing distance from the driver chip 20. This geometry also hold similarly for a lead wire group comprised of the lead wires 12d to 12j. In this example, since the insulating layer 11 has transparency, the lead wires 12 covered with the insulating layer 11 can be checked visually from an appearance of the driver assembly 100. The insulating layer 11 may be an opaque layer.

As shown in FIG. 1 and FIG. 2, a device hole H1 is provided around the driver chip 20. The device hole H1 is an opening formed in the film layer 13 of the wiring sheet 10. The sealing resin 15 is poured through the device hole H1 and is applied to the driver chip 20 and the wiring sheet 10, whereby a position of the driver chip 20 bump-coupled to the lead wire 12 is fixed to the wiring sheet 10. If the sealing resin 15 is opaque, it will become impossible to recognize the device hole H1 from the appearance of the driver assembly 100.

As shown in FIG. 3, the wiring sheet 10 and the radiator plate 30 are adhered together by interposing the adhesive agent 40 therebetween. The driver chip 20 is sandwiched between the wiring sheet 10 and the radiator plate 30 in a vertical direction. Incidentally, an application range of the adhesive agent 40 is arbitrary. What is preferably necessary is just to apply the adhesive agent 40 to at least both sides of the driver chip 20 that is sandwiched therebetween.

The adhesive agent 40 is an acrylic adhesive, for example. A double-sided tape may be utilized as the adhesive agent 40. The double-sided tape is a separator (base material) on whose surface an adhesive layer is deposited. The adhesive layer can be provided over the radiator plate 30, for example, by pressing the separator with an adhesive layer to the radiator plate 30 and peeling off the separator from the radiator plate 30. By placing the radiator plate 30 with the adhesive layer over the wiring sheet 10, the both members are adhered together in an instant.

As shown in FIG. 3, the wiring sheet 10 is a laminate member in which the insulating layer 11, the lead wire layer 12, and the film layer 13 are layered. A material and the thickness of the film layer 13 are selected so that the flexibility of the wiring sheet 10 can be secured. The film layer 13 is made up of a resin, such as polyimide, for example. The lead wire layer 12 should just have conductivity, for example, and is made up of a metal material, such as aluminum (Al) and copper (Cu), an electric conductive resin, etc. The insulating layer 11 clothes the lead wire layer 12. The insulating layer 11 is made up of a solder resist etc., for example. Electric coupling is secured in a contact region where the lead wire layer 12 exposes itself from the insulating layer 11.

As shown in FIG. 3, the radiator plate 30 is press worked so as to have a concave part 36, and has a shape where a flat part 31, a slope part 32, a flat part 33, a slope part 34, and a flat part 35 continue. The flat part 31 and the flat part 35 exist in the same xy-plane. The slope part 32 connects the flat part 31 and the flat part 33. The flat part 33 exists in an xy-plane that is different from that of the flat parts 31, 35. The slope part 34 connects the flat part 33 and the flat part 35. Incidentally, since the radiator plate 30 is tabular, a convex part 37 is formed according to the concave part 36. The radiator plate 30 is a metal plate, such as of aluminum (Al) and stainless steel (SUS).

In the case where the radiator plate 30 is formed by press working of an aluminum plate, it is desirable that the thickness of the aluminum plate to be processed should be not less than 0.3 mm and less than 2 mm. The reason why a thickness of 0.3 mm or more is necessary is to secure rigidity enough to maintain the shape of the concave part 36 by the press working. Moreover, this is also because when the concave part 36 is intended to be formed on an aluminum plate of a thickness of 2 mm or more by press working, With the press working burr etc. occurs and is likely to become metal trash, and therefore the press working is accompanied with a decrease in reliability or an increase in manufacturing cost. In the case where the radiator plate 30 is formed by press working a stainless steal plate, it is desirable that the thickness of the stainless steel plate to be worked is not less than 0.1 mm and less than 1 mm. The reason whey a thickness equal to 0.1 mm or more is necessary is to secure the rigidity of keeping a shape of the concave part 36 by press working. Moreover, this is because the cost will increase if a stainless steel plate equal to 1 mm or more is intended to be press worked. Also in the case where the radiator plate 30 is formed from other materials, similarly it is desirable that a material that can suppress a formation cost is selected within a range of a condition that makes possible attainment of a necessary radiation effect.

As compared with the wiring sheet 10 having flexibility, the radiator plate 30 has rigidity. In other words, the radiator plate 30 does not have flexibility comparable to that of the wiring sheet 10. In a range R10 shown in FIG. 3, mechanical strength is secured by the radiator plate 30.

The concave part 36 of the radiator plate 30 is a housing part for partially housing the driver chip 20. As is clear from the explanation in the introduction, in this embodiment, the depth profile of the concave part 36 of the radiator plate 30 is set so that the wiring sheet 10 may approach toward the radiator plate 30 side as the wiring sheet 10 extends in such a direction so as to separate from the driver chip 20. As is clear from FIG. 3, the wiring sheet 10 has a portion that approaches toward the radiator plate 30 side as the wiring sheet 10 separates from the driver chip 20. In other words, a concave part 17 is provided also on the wiring sheet 10. The concave part 17 has a slope 17a as its internal face. Incidentally, as shown in FIG. 3, the slope 17a is not necessarily formed in the form of a flat plane, and it may become in the form of a warped plane.

The reason why a slop portion is provided in the wiring sheet 10 is mainly that the depth of the concave part 36 of the radiator plate 30 is set shallower than the thickness of the driver chip 20. In a state shown in FIG. 3, the driver chip 20 is sandwiched between the wiring sheet 10 and the radiator plate 30 in the state of receiving a stress in such a direction so as to be contracted vertically, which makes the thermal coupling between the driver chip 20 and the radiator plate 30 more sufficient.

Although a concrete mechanism of enhancing the reliability of the thermal coupling between the driver chip 20 and the radiator plate 30 depends on an individual case, a content of technological examination in a current stage is as described above. That is, when the radiator plate 30 makes thermal expansion more largely than the wiring sheet 10 does, the wiring sheet 10 adhered to the radiator plate 30 will be pulled in an expansion direction according to expansion of the radiator plate 30, and the driver chip 20 mounted on this wiring sheet 10 will be biased to the radiator plate 30 side. This is because the wiring sheet 10 approaches toward the radiator plate 30 side as the wiring sheet 10 extends in such a direction so as to separate from the driver chip 20 by the depth profile setting of the concave part 36. Incidentally, as shown in FIG. 3, an upper long arrow shows expansion of the radiator plate, and lower short arrows show expansion of the wiring sheet 10. The length of the arrow shows the amount of expansion schematically, and the figure shows that the amount of expansion of the radiator plate 30 is larger than the amount of expansion of the wiring sheet 10 (film layer 13).

More specifically, consider a case where the radiator plate 30 is of aluminum, a reinforcing member of the wiring sheet 10 is of polyimide, and the driver chip 20 is of silicon. The linear expansion coefficient of aluminum is about 23 ppm/° C., the linear expansion coefficient of polyimide is about 5-10 ppm/° C., and the linear expansion coefficient of silicon is about 2.4 ppm/° C. Although the polyimides have a large width of linear expansion coefficients that depend on their compositions, the polyimide is modified to have an expansion coefficient value close to that of a glass (linear expansion coefficient of about 8 ppm/° C.) that is a main material of the display panel, so that accuracy of outer lead bonding can be increased.

Explaining it with FIG. 4, when ambient temperature changes from a temperature of about 25° C. at the time of manufacture of the driver assembly to a maximum temperature (of about 125° C.), the length between the inner sides of the right-hand side and left-hand side adhesive agent 40 of the radiator plate 30 is expanded by about 23 ppm/° C.×100° C.≈2,300 ppm at a maximum in a y-direction, and the wiring sheet is expanded by about 8 ppm/° C.×100° C. 800 ppm in the y-direction. A minimum value of an angle of inclination is designed according to the length of the slope part of the wiring sheet 10 so as to be able to absorb this difference of about 1,500 ppm.

Moreover, at this time, simultaneously, the depth D of the concave part 36 of the radiator plate 30 also becomes deep by about 2,300 ppm, and the height H of the driver chip 20 becomes high by about 2.4 ppm/° C.×100° C.≈240 ppm. The angle of inclination is designed according to the length of the slope part of the wiring sheet 10 so that this difference may become as small as possible.

As shown in FIG. 4, taking the rear face of the flat part 33 as a reference plane, a gap D from that plane to the top face of the wiring sheet 10 located outside a slope position of the wiring sheet 10 is narrower than a gap H from that plane to the top face of the wiring sheet 10 located inside the slope position of the wiring sheet 10. By this, sufficient deformation can be given to the wiring sheet 10, and thereby the reliability of the thermal coupling between the driver chip 20 and the radiator plate 30 can be enhanced effectively. Incidentally, a range R20 shown in FIG. 4 corresponds to the formation range of the device hole H1.

As is shown in detail in FIG. 5 together with FIG. 4, the driver chip 20 has a semiconductor substrate 21 and a wiring layer 22, the semiconductor substrate 21 is thinned by polishing etc. from its backside, and a roughened surface S21 is formed on the backside. Thinning of the semiconductor substrate 21 makes it possible to transfer heat generated by an active element (not illustrated) formed in the front of the semiconductor substrate 21 to the radiator plate 30 more effectively. It is natural that a processing whereby the backside of the semiconductor substrate 21 is made to mirror finish and thereby a contact area between the backside and the radiator plate 30 is widened is advantageous in terms of radiation of heat. However, since mirror finish pushes the cost high, the manufacturing cost of the driver chip 20 is intended not to be increased by remaining the roughened surface S21 as it is. However, with an effect of the heat conductive grease 50, sufficient thermal coupling between the semiconductor substrate 21 and the radiator plate 30 can be realized. Incidentally, as shown in FIG. 4 and FIG. 5, the driver chip 20 is electrically coupled to the lead wire through a bump 16.

The grease 50 has a semisolid having thermal conductivity and high viscosity. Suitably, the grease 50 is silicone grease. In order to improve the thermal conductivity of the grease 50, it is preferable to mix filler having high thermal conductivity, such as silver, into it. The grease 50 has fluidity as compared with the adhesive agent 40. There are many adhesive agents 40 that are solidified by deformation and their fluidities are not high. On the other hand, the grease 50 has viscosity in normal temperature, and has a certain degree of fluidity. In addition, when a stress is given to the component parts of the driver assembly 100 from the outside, the thermal coupling between the driver chip 20 and the radiator plate 30 is suitably secured by the fluidity of the grease 50. In addition, when the driver assembly 100 is bent in the U-shaped form and a stress is given to the whole body of it, the thermal coupling between the driver chip 20 and the radiator plate 30 is suitably secured by the fluidity of the grease 50. Even if the component parts of the driver assembly 100 expand or contract by an influence of heat, the thermal coupling between the driver chip 20 and the radiator plate 30 is suitably secured by the fluidity of the grease 50. Incidentally, it is desirable that the layer thickness of the grease 50 should be a necessary and sufficient degree to bury the concave part produced on the roughened surface S21. By limiting the layer thickness of the grease 50, it is possible to make a radiation characteristic from the driver chip 20 to the radiator plate 30 an excellent one.

A method for producing the driver assembly 100 will be explained with reference to FIG. 6 to FIG. 8. Note that a manufacture procedure to be explained below can be appropriately modified by a person skilled in the art, and the technical scope of the present invention should not be narrowly interpreted from the following explanation.

First, as shown in FIG. 6, the driver chip 20 is mounted on the wiring sheet 10 by bump interconnection to electrically connect the terminal of the driver chip 20 and the lead terminal 12 of the wiring sheet 10. In this state, the wiring sheet 10 exists being substantially flat. Next, the sealing resin 15 is poured from the above, when taking a frontal view of FIG. 6, through the device hole H1. The poured-in resin fills the a space between the driver chip 20 and the wiring sheet 10 after going around a lower part under the wiring sheet 10 through the device hole H1. The sealing resin 15 may be of either a heat-curable type or a UV-curable type, and a material of another type may be used. Thus, as shown in FIG. 6, the driver chip 20 is mounted on the wiring sheet 10. Incidentally, it is assumed that the wiring sheet 10 shall be separately manufactured by practical use of a usual semiconductor process.

The radiator plate 30 goes through a process shown in FIG. 7 separately. First, a tabular metal plate is press worked and formed into a shape as shown in FIG. 7A. Next, the grease 50 is applied on the bottom of the concave part of the radiator plate 30, as shown in FIG. 7B. Next, the adhesive agent 40 is applied on a brim part (corresponding to the flat parts 31, 35) located in the outer circumference of the concave part of the radiator plate 30, as shown in FIG. 7C.

In order to improve workability, double-sided tape may be used as the adhesive agent 40. By pressing a separator with the adhesive layer on it to the radiator plate 30 and peeling off the layer, the adhesive layer on the separator is adhered over the radiator plate 30.

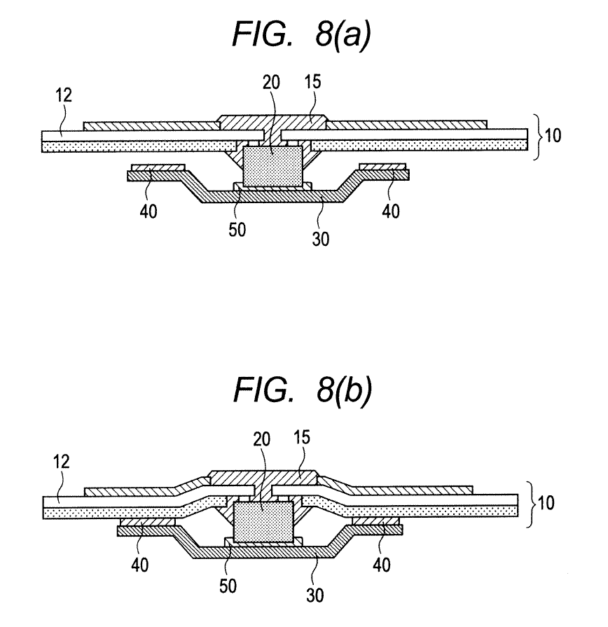

Next, as shown in FIG. 8, the part shown in FIG. 6 and the part shown in FIG. 7 are pasted together. To be concrete, as shown in FIG. 8A, the driver chip 20 is placed over the bottom of the concave part of the radiator plate 30, and the grease 50 applied to the bottom of the concave part of the radiator plate 30 and the driver chip 20 are made to contact.

Next, as shown in FIG. 8B, the wiring sheet 10 is made to adhere to the brim part of the radiator plate 30, and the radiator plate 30 and the wiring sheet 10 are made to adhere together through the adhesive agent 40 that has been applied to the brim part of the radiator plate 30 in advance. Incidentally, a heat-curable or UV-curable adhesive may be used as the adhesive agent 40. However, in this case, in order to secure the rapidity of adherence, preferably, use of the UV-curable adhesive is recommended.

Below, a supplementary explanation will be given for a point that the reliability of the thermal coupling between the semiconductor chip and the radiating member can be improved. Incidentally, let it be assumed that according to examination in a current stage, even if a content of its explanation includes misconception, it will not affect the technical scope of this application of the present invention.

When the driver assembly 100 performs a normal operation in the display, there arises heat originating from other parts in the display or heat accompanying the operation of the driver chip 20. In response to these heats, the radiator plate 30 and the driver chip 20 expand largely. On the other hand, as compared with them, the wiring sheet 10 does not expand thermally so much.

Positional variation between the radiator plate 30 ad the driver chip 20 in the plane (xy-plane of FIG. 3) is absorbed by the grease 50 having fluidity. Therefore, the thermal coupling of the driver chip 20 and the radiator plate 30 is not spoiled because of the grease 50.

The positional variation between the radiator plate 30 and the wiring sheet 10 is absorbed by the grease 50 having fluidity. Since the wiring sheet 10 is also pulled toward the outside in the plane according to planar expansion of the radiator plate 30, the concave part of the wiring sheet 10 is displaced in such a direction that the concave part becomes shallow, and the driver chip 20 is displaced to the radiator plate 30 side. By this, a form in which the driver chip 20 is sandwiched between the wiring sheet 10 and the radiator plate 30 in the vertical direction can be realized, and thereby adhesion between the driver chip 20 and the radiator plate 30 can be increased sufficiently. Since the grease 50 lies between the radiator plate 30 and the driver chip 20, it is controlled that this increment in adhesion may cause stress.

The positional variation in a vertical plane (zy-plane of FIG. 3) between the radiator plate 30 and the driver chip 20 is absorbed by the grease 50 having fluidity. Therefore, it is reduced that a mechanical stress is given from the radiator plate 30 to the driver chip 20. It is also the same in a reverse case.

There is a case where the driver assembly 100 may be bent in the U-shaped form etc. Also, in this case, the thermal coupling between the driver chip 20 and the radiator plate 30 is suitably secured by the grease 50.

### Second Embodiment

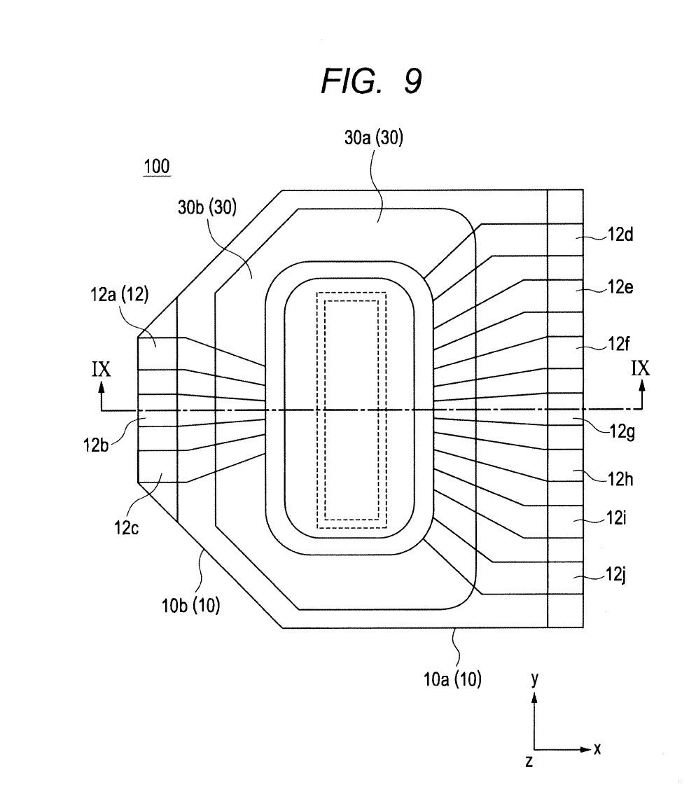

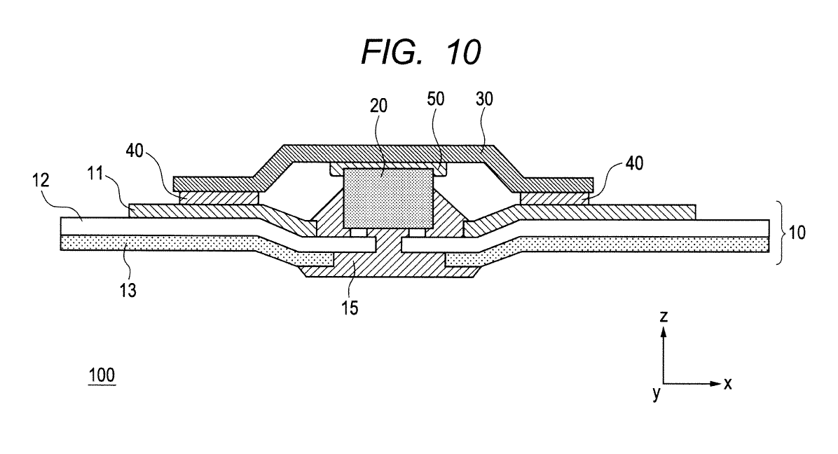

A second embodiment will be explained with reference to FIG. 9 and FIG. 10. In this embodiment, a wiring sheet 10 whose configuration is different from that of the first embodiment is used. Even in this case, the embodiment can attain the same effect as that of the first embodiment.

As typically shown in FIG. 9 and FIG. 10, the lead wire layer 12 is layered over the film layer 13. As shown in FIG. 10, the film layer 13, the lead wire layer 12, and the insulating layer 11 are layered in this order. An inner lead bonding part and an outer lead bonding part are arranged on the same side.

### Third Embodiment

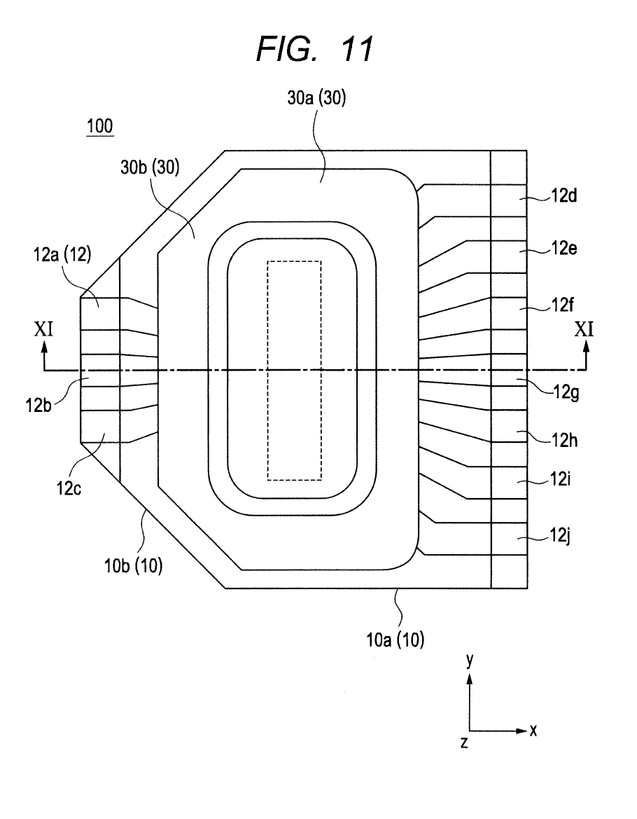

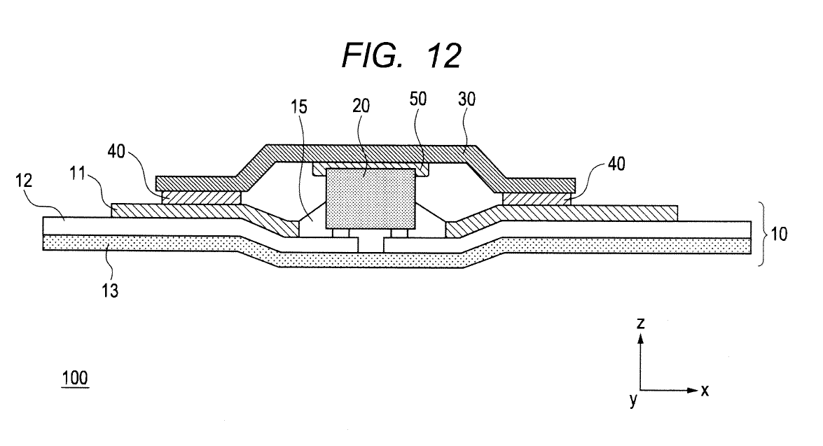

A third embodiment will be explained with reference to FIG. 11 and FIG. 12. In this embodiment, a wiring sheet 10 of a configuration different from those of the first and second embodiments is used. Even in this case, the embodiment can attain the same effect as the first and second embodiments have.

As typically shown in FIG. 11 and FIG. 12, the opening as a device hole is not provided in the film layer 13. As shown in FIG. 12, the sealing resin 15 will be poured in from the transverse direction of the driver chip 20 mounted over the wiring sheet 10. This makes unnecessary a step of forming the opening in the wiring sheet 10. Therefore, it becomes possible to attain lowering of the cost of the driver assembly 100. Furthermore, since the intensity of the film layer 13 for supporting the opening becomes unnecessary, the film can be made thin, and therefore it becomes possible to lower the cost of the driver assembly 100 and attain flexibility that is more pliant.

### Fourth Embodiment

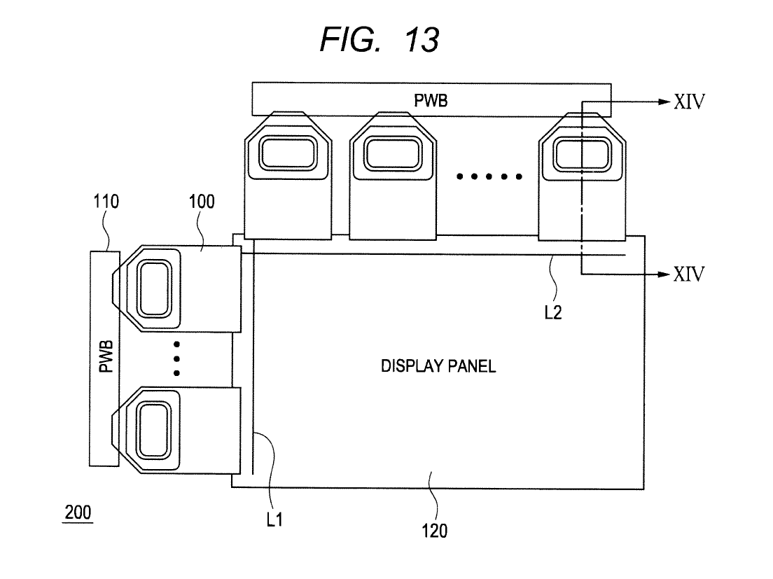

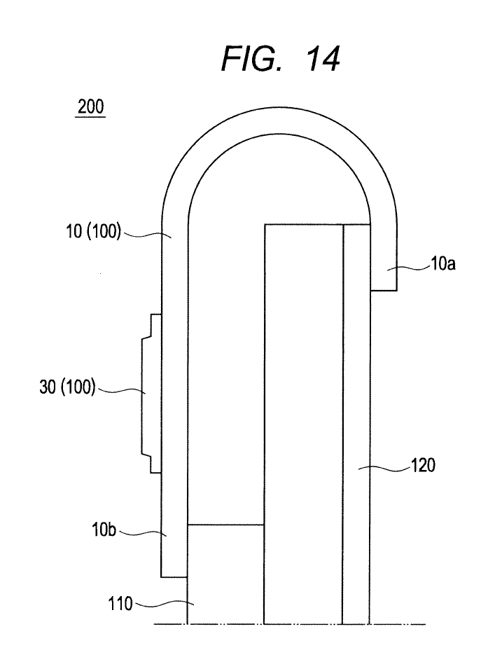

A fourth embodiment will be explained with reference to FIG. 13 and FIG. 14. In this embodiment, a display into which the driver assembly 100 disclosed in the first to third embodiments is integrated is disclosed. Even in such a case, this embodiment can attain the same effect as the first to third embodiments have.

As shown in FIG. 13, a display 200 includes multiple driver assemblies 100, multiple printed circuit boards 110, and a display panel 120. The driver assembly 100 is bonded to the printed circuit board 110 by outer lead bonding, and is also bonded to the display panel 120 by outer lead bonding. Incidentally, a data line L1 and a scanning line L2 are formed in the display panel 120 in the form of a grid, and pixels are provided at intersections of the data line L1 and the scanning line L2. A predetermined value is supplied to a pixel selected by the scan line through the data line. Incidentally, as for kinds of display panels, a plasma display panel, a liquid crystal display panel, an organic electroluminescence display panel, etc. are exemplified.

The driver assembly 100 is provided between the printed circuit board 110 and the display panel 120 being bent in the U-shaped form as shown in FIG. 14. The lead wire exposed at an edge side of the rectangular part 10a of the wiring sheet 10 is coupled to a terminal provided in the display panel 120. The lead wire exposed in an edge side of the taper part 10b of the wiring sheet 10 is coupled to a terminal provided on the printed circuit board 110. Incidentally, the printed circuit board 110 is installed on the backside of the display panel 120. By giving flexibility to the driver assembly 100 and connecting the printed circuit board 110 and the display panel 120, it becomes possible to make small an area of a frame surrounding the display panel 120.

The present invention is not limited to the above-mentioned embodiments, and can be modified appropriately within a scope that does not deviate from the gist of the invention. The semiconductor chip is not restricted to the driver element of the display, and may be various other functional elements. Concrete shapes, materials, etc. of the wiring member and the radiating member are arbitrary. Each embodiment is not mutually independent and each and the other can be combined or done in other way appropriately, and the inventors can claim their synergistic effect.

1. A semiconductor device comprising:
a sheetlike wiring member on which lead wires are provided;
a semiconductor chip that is mounted over the wiring member and is electrically coupled to the lead wires; and
a radiating member on which a housing part for partially housing the semiconductor chip and that is thermally coupled to the semiconductor chip;
wherein the wiring member and the radiating member are adhered to each other so as to sandwich the semiconductor chip housed in the housing part, and
wherein the depth profile of the housing part is set up so that the wiring member may approach toward the radiating member as the wiring member extends in such a direction so as to separate from the semiconductor chip.

2. The semiconductor device according to claim 1, further comprising a fluid material that assists heat transfer from the semiconductor chip to the radiating member.

3. The semiconductor device according to claim 1, further comprising adhesive agent for mutually adhering the wiring member and the radiating member.

4. The semiconductor device according to claim 1,
wherein a thermal expansion coefficient of the radiating member is larger than a thermal expansion coefficient of a resin layer that is a constituent layer of the wiring member.

5. The semiconductor device according to claim 1,
wherein a position of the semiconductor chip is fixed to the wiring member through a sealing material.

6. The semiconductor device according to claim 1,
wherein the wiring member has flexibility and the radiating member is hard as compared with the wiring member.

7. The semiconductor device according to claim 1,
wherein the radiating member is a tabular metal plate, and a concave part functioning as the housing part is provided in the metal plate.

8. The semiconductor device according to claim 1,
wherein the semiconductor chip is a driving element of a display.

9. A display comprising:
the semiconductor device according to claim 1;
a substrate to which the lead terminal of the wiring substrate is electrically coupled; and
a display panel to which the lead terminal of the wiring substrate is electrically coupled.

10. A method for producing a semiconductor device comprising the steps of:
electrically connecting a semiconductor chip to a sheetlike wiring member on which lead wires are provided;
forming a housing part for partially housing the semiconductor chip on a radiating member;
housing the semiconductor chip in the housing part of the radiating member and thermally connecting the semiconductor chip thereto;
after the steps above, adhering the wiring member and the radiating member to each other by setting a depth profile of the housing part so that the wiring member may approach toward the radiating member as the wiring member extends in such a direction so as to separate from the semiconductor chip.
